(19) United States
(12) Patent Application Publication
(10) Pub. No.: US 2011/0180788 A1
(43) Pub. Date: Jul. 28, 2011

(54) COMPOUND SEMICONDUCTOR THIN FILM WITH ANTI-FOG FUNCTION AND THE MANUFACTURING METHOD THEREOF

(76) Inventors: Chuang-I CHEN, Kaohsiung City (TW); Cheng-Jye Chu, Kaohsiung City (TW); Ruei-Ming Huang, Kaohsiung City (TW)

(21) Appl. No.: 13/013,626

(22) Filed: Jan. 25, 2011

(30) Foreign Application Priority Data
Jan. 26, 2010 (TW) 99102104

(51) Int. Cl. H01L 51/30

(52) U.S. Cl. 257/40; 438/99; 257/E51.024

(57) ABSTRACT

The disclosure is a compound semiconductor thin film with anti-fog function and the manufacturing method thereof. The thin film at least includes a dense semiconductor thin film combined with a porous-needle semiconductor thin film. The disclosed compound semiconductor thin film decreases the contact angle of water and achieves hydrophilic and anti-fog properties for a long lifetime.

### CROSS-REFERENCES TO RELATED APPLICATIONS

This non-provisional application claims priority under 35 U.S.C. §119(a) on Patent Application No. 99102104 filed in Taiwan, R.O.C. on 2010/1/26, the entire contents of which are hereby incorporated by reference.

### BACKGROUND OF THE INVENTION

1. Field of the Invention

The present invention generally relates to a compound semiconductor thin film, and more particularly to a compound semiconductor thin film with an anti-fog function and the manufacturing method thereof.

2. Description of the Related Art

Anti-fog function products can be used for transportation, aerospace, household and the other products. For example, a car rearview mirror surface coating with a layer of dense titanium oxide can let the water or water vapor in the air condense to form a water membrane with uniform spreading, so the fog which can result light scattering will not occur on the surface. When it rains, the rain water can spread rapidly into a uniform water membrane (rather than causing water droplets to obstruct the driver's view), improving driving safety.

Current anti-fog function products have good hydrophilic properties which can achieve a good anti-fog and self-cleaning function. Anti-fog function product materials can be selected from the composite structures consisting of metal oxides (TiO₂/ZnO, SnO₂/SrTiO₃, SiO₂/SnO₂, SnO₂/WO₃, SnO₂/Bi2O₃, and SnO₂/Fe₂O₃) or metals (Pt, Pd, Rh, Ru, Os, and Ir).

However, most of the anti-fog function product materials are prepared by combining titanium dioxide and silicon dioxide particles in the way of adding or bonding. The production process of hydrophiles is as follows. When titanium dioxide or silicon dioxide is under UV irradiation, the electrons of the titanium dioxide or silicon dioxide are excited from the valence band into the conduction band. They migrate to the surface of titanium dioxide or silicon dioxide forming electron-hole pairs on the surface and then generate the vacancies of metal ions and oxygen. At this time, the adsorbed water molecules in the air are dissociated to chemically adsorbed water, and the surroundings of metal ions defects will form a highly hydrophilic region. The function of self-cleaning surface is due to the strong oxidation and thin film super-hydrophile when titanium oxide or silicon dioxide is undergoing UV excitation. Since titanium oxide has a hydrophilic surface, the dirt cannot adhere to it easily. After photocatalysis of titanium dioxide, the organic substances on the surface may be decomposed into carbon dioxide and water, and inorganic substances can be washed away and cleaned up via rain.

Titanium dioxide or silicon dioxide can be made by means of the sol-gel method, chemical vapor deposition (CVD), liquid phase deposition (LPD), etc. Of these methods, the titanium dioxide or silicon dioxide prepared from the sol-gel method can be made into any shape, such as powders, bulk materials, films, etc., and the samples have high purity and high uniformity, etc.

Furthermore, under the sol-gel system reaction process of the titanium oxide, it can be found that the larger alkyl group of precursor makes the slower hydrolysis reaction and the diffusion rate and results the smaller polymers. In order to obtain a titanium dioxide with larger overall density and smaller pore, acid catalysts must be added (such as HCl, HNO₃, etc.), to achieve a larger surface area. However, although adding acid catalyst helps the hydrolysis condensation reaction, it is not conducive to the condensation reaction, resulting in longer gel formation time and preventing quick formation of titanium oxide thin film.

U.S. Pat. No. 5,320,782 entitled “Acicular or platy titanium suboxides and process for producing same”, discloses that titanium dioxide has a porous structure, but it cannot produce titanium dioxide particles in needle-shapes with uniform length. It can only produce mixed particles of which the quantity of the shorter particles is larger than the longer ones; post-processing and refinement process is therefore required in order to obtain the longer particles. However, in terms of mass production, isolating the longer ones from the mixed titanium dioxide particles by refinement process is not easy and increases consumption costs.

U.S. Pat. No. 5,597,515 entitled “Conductive, powdered fluorine-doped titanium dioxide and method of preparation”, discloses that using a different proportion of fluoride in titanium dioxide can achieve the required electrical conductivity. However, it is not clearly revealed how the porous relationship between fluoride and titanium dioxide improves the strength and activity of the film. In order to obtain small titanium particles, some scholars have proposed extracting metals from the single crystal of the fibrous metal titanate. However, this method easily damages the fiber shape, thereby reducing particle strength and increasing preparation complexity.

Other research, demonstrates that improvements in the quality of hydrophilic, anti-fog and self-cleaning properties can be realized by changing the different operating conditions such as different coating times, thermal treatment in different temperatures, different amounts of SnO₂ additives, the relationship of the pores of TiO₂, the strength and activity of the film, etc. However, this has not resulted in hydrophilic anti-fog film with the best, most lasting, stable, and high level of hardness.

### BRIEF SUMMARY OF THE INVENTION

The applicants have persevered with carefully testing and research, and finally developed a compound semiconductor thin film with anti-fog function, as well as the manufacturing method thereof. By using the method, a compound semiconductor thin film is produced which can decrease the contact angle of water and extend the anti-fog life time in lower temperature conditions under lower temperature conditions. The present invention refers to U.S. Pat. No. 5,320,782 Notice and U.S. Pat. No. 5,597,515 cited references.

It is an objective of the present invention to provide a compound semiconductor thin film with an anti-fog function. It combines a dense semiconductor thin film and a porous-needle semiconductor thin film to create a hydrophilic thin film which can decrease the contact angle of water and achieve long anti-fog lifetime.

It is the second objective of the present invention to provide a method of preparing compound semiconductor thin film with an anti-fog function. Under lower temperature conditions, a compound semiconductor thin film can be produced which decreases the contact angle of water and extends the lifetime of the anti-fog.

The present invention provides a compound semiconductor thin film with an anti-fog function, including: a first semiconductor thin film and a second semiconductor thin film. The first semiconductor thin film is coated on a substrate surface. The first semiconductor thin film is compounded from a metal organic compound and a hydrocarbon compound. It forms a dense structure at the first heating temperature between 300° C. and 1000° C. The second semiconductor thin film is coated on the surface of the first semiconductor thin film. The second semiconductor thin film is compounded from metal organic compounds, hydrocarbon compound and an organic additive. It forms a porous-needle structure at the second heating temperature between 300° C. and 1000° C. The size of porous-needle structure is between 1 nm and 25 nm.

The present invention still provides a method of preparing compound semiconductor thin films with anti-fog function, including the following steps: putting a metal organic compound and a hydrocarbon compound into a reaction system to form a first sol, and the reaction system temperature is between 25° C. and 200° C.; dipping a substrate in the first sol to form a first semiconductor thin film on the substrate surface; using a first heating temperature between 300° C. and 1000° C. to heat the first semiconductor thin film to form a dense structure; putting the metal organic compound, the hydrocarbon compound and an organic additive into the reaction system to form the second sol; dipping the first semiconductor thin film in the second sol to form a second semiconductor thin film on the surface of the first semiconductor thin film; and using the second heating temperature between 300° C. and 1000° C. to heat the second semiconductor thin film to form a porous-needle structure with size between 1 nm and 25 nm.

### BRIEF DESCRIPTION OF THE DRAWINGS

All the objects, advantages, and novel features of the invention will become more apparent from the following detailed description when taken in conjunction with the accompanying drawing.

FIG. 1 is a compound semiconductor thin film with anti-fog function;

FIG. 2 is a method of preparing compound semiconductor thin film with anti-fog function;

FIG. 3 is the simple flowchart of preparing the compound semiconductor thin film with anti-fog function; and

FIG. 4 is the SEM image of the first semiconductor thin film.

### DETAILED DESCRIPTION OF THE INVENTION

Although the invention has been explained in relation to several preferred embodiments, the accompanying drawings and the following detailed descriptions are the preferred embodiment of the present invention. It is to be understood that the following disclosed descriptions will be examples of the present invention, and will not limit the present invention to the drawings and the special embodiment.

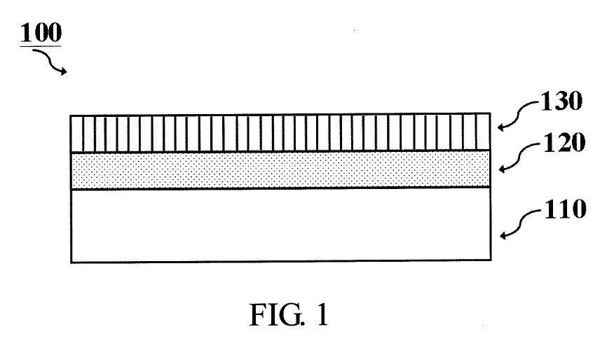

Please refer to FIG. 1, which is a compound semiconductor thin film with the anti-fog function 100, including a first semiconductor thin film 120, a substrate 110, and a second semiconductor thin film 130. The first semiconductor thin film 120 is coated on the surface of substrate 110. The first semiconductor thin film 120 is compounded from a metal organic compound 190 and a hydrocarbon compound 180. It forms a dense structure at the first heating temperature. The second semiconductor thin film 130 is coated on the surface of the first semiconductor thin film 120. The second semiconductor thin film 130 is compounded from the metal organic compounds 190, the hydrocarbon compounds 180 and an organic additive 170. It forms a porous-needle structure with size between 1 nm to 25 nm a second heating temperature. The substrate of the present invention is selected from the group consisting of the glass substrate and the ceramic substrate. Preferably, the first heating temperature and second heating temperature are between 300° C. and 1000° C.

The first semiconductor thin film 120 of the present invention can absorb energy from the visible light, sunlight or UV light. After the energy is absorbed by the dense surface structure, it can be transferred directly to the first semiconductor thin film 120 which can store the energy. The energy is absorbed via the tip of the second semiconductor thin film 130 and then be transferred directly to the first semiconductor thin film 120. After stopping supplying energy, the first semiconductor thin film 120 which has stored the energy starts to transfer energy slowly to the second semiconductor thin film 130 which can releases energy and has a porous-needle structure. At this time, the tip of the second semiconductor thin film 130 starts to release energy and then decrease the contact angle of water droplets to form a uniform water membrane. Therefore, the present invention uses a new technology which can decrease the contact angle of water to extend the utility time after light irradiation, and develops a new sol material which has semiconductor characteristics to create the hydrophilic thin film which can decrease the contact angle of water and achieves long anti-fog lifetime. The organic additive 170 in this present invention is selected from the group consisting of the polyols, hydrocarbons and high polymer.

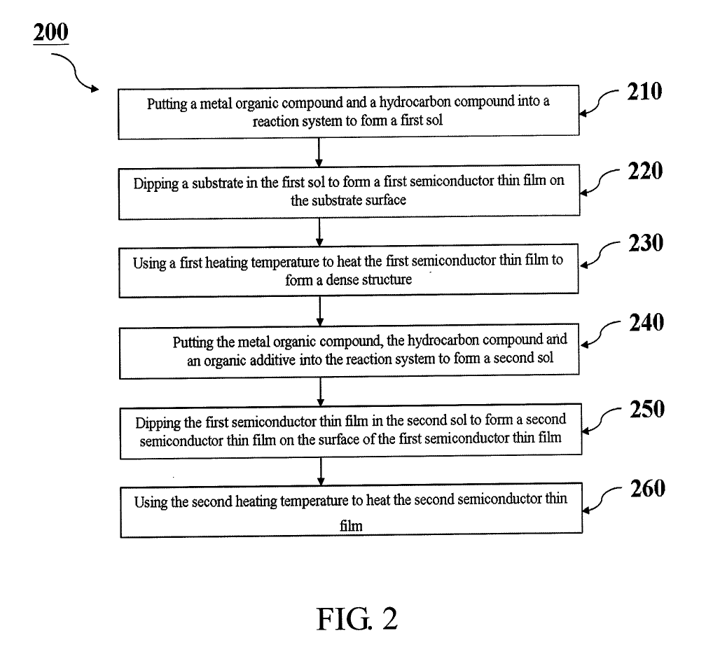

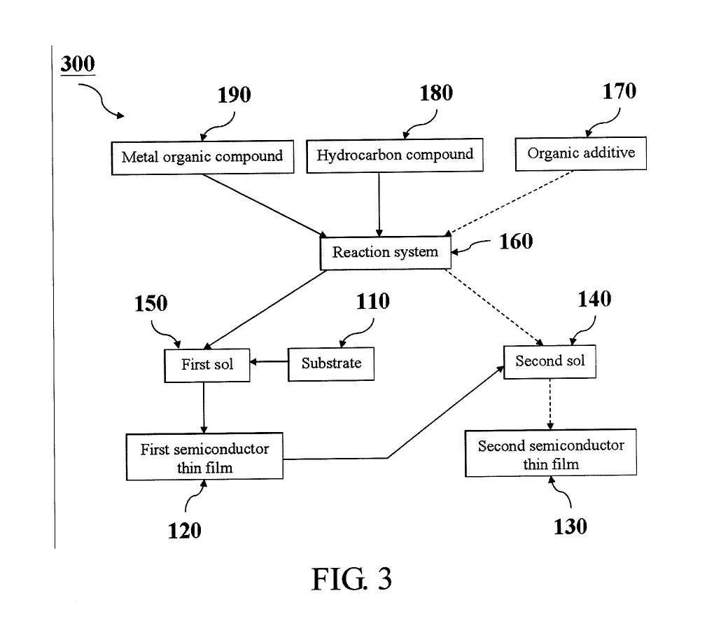

Please refer to FIG. 2 and FIG. 3, which is the method 200 of preparing compound semiconductor thin film with anti-fog function 100 and its diagram 300, including:
Step 210: putting a metal organic compound 190 and a hydrocarbon compound 180 into a reaction system 160 to form a first sol 150, and the temperature of the reaction system 160 is between 25° C. and 200° C.;
Step 220: dipping a substrate 110 into the first sol 150 to form a first semiconductor thin film 120 on the substrate 110 surface.
Step 230: using a first heating temperature between 300° C. and 1000° C. to heat the first semiconductor thin film 120 at a first heating temperature between 300° C. and 1000° C. to form a dense structure.
Step 240: putting the metal organic compound 190, the hydrocarbon compound 180, and an organic additive 170 into the reaction system 160 to form a second sol 140.
Step 250: dipping the first semiconductor thin film 120 into the second sol 140 to form a second semiconductor thin film 130 on the surface of the first semiconductor thin film 120.
Step 260: heating the second semiconductor thin film 130 at a second heating temperature between 300° C. and 1000° C. to form a porous-needle structure with pore size between 1 nm and 25 nm.

Preferably, from step 230 to step 260 the ideal temperature range of the first temperature and the second temperature is between 400° C. and 600° C. The metal organic compound is selected from the group consisting of (OR)ₓ M-O-M(OR)ₓ, (R)_{y}(OR)_{x-y} M-O-M(OR)_{x-y}(R)_{y}, M(OR)ₓ, M(OR)_{x-y}(R)_{y}, (OR)ₓ M-O-M(OR)ₓ. R is selected from the group consisting of alkyl-base, alkenyl-base, aryl-base, haloalkyl-base, hydrogen. M is selected from the group consisting of Al, Fe, Ti, Zr, Hf, Si, Rh, Cs, Pt, In, Sn, Au, Ge, Cu, and Ta. Among them, x>y, x is one of 1, 2, 3, 4, and 5, and y is one of 1, 2, 3, 4, and 5. Furthermore, the hydrocarbon compound 180 is selected from the group consisting of alcohols, ketones, ethers, phenols, aldehydes, esters, and amines. It should be noted that the metal organic compound 190 is selected from the group consisting of Ti(OR)₄, Si(OR)₄, (NH₄)₂Ti(OR)₂, CH₃Si(OCH₃)₃, Sn(OR)₄, and In(OR)₃. The hydrocarbon compound 180 is selected from the group consisting of C₂H₅OH, C₃H₇OH, C₄H₉OH, CH₃OC₂H₅, and CH₂O. The organic additive 170 is selected from the group consisting of polyols, hydrocarbon compounds, and polymers.

The present invention proposes that by means of two different stages of the first semiconductor thin film 120, the second semiconductor thin film 130, the first and second temperature heat treatment can satisfy efficiently the two factors referred to previously. From this description we can know that the preparation methods of the first semiconductor thin film 120, the second semiconductor thin film 130, the first sol 150 and the second sol 140, which have the abilities of storage, absorption and release, in the present invention can use the two-stages manufacturing processes. First, the metal organic compounds 190 and the hydrocarbon compounds 180 will be sent in advance to the chemical reactor. Next, control temperature, air, water, and add solvents. Place the metal organic compounds 190 and the hydrocarbon compounds 180 into the first sol 150 with semi-liquid and semi-gel. Dip coat the substrate 110 with a high temperature heat treatment method to form the first semiconductor thin film 120. Again, the metal organic compounds 190, the hydrocarbon compounds 180 and an organic additive 170 will be sent in advance to the chemical reactor for synthesis. Again, control temperature, air, water and add solvents. Place the metal organic compounds 190, the hydrocarbon compounds 180 and the organic additive 170 into the second sol 140 with semi-liquid and semi-gel. Dip coat the substrate 110 in a high temperature heat treatment method to form the second semiconductor thin film 130 on the first semiconductor thin film 120.

The first semiconductor thin film 120 and the second semiconductor thin film 130 form two types. One of them is a flat and dense thin film which can store the energy, and the other is a porous-needle thin film which can absorb and release the energy. When comparing this obtained product to similar products (such as hydrophile, defogging or self-cleaning), the maximum benefit discovered is extending and maintaining the low contact angle of water, which can achieve better product functionality related to hydrophile, defogging or self-cleaning, in addition to the difference of utilized materials and formation structures. Use of the first sol 150 and the second sol 140 in the dipping process can reduce the costs and the amount of pollution generated.

Furthermore, the high-temperature heat treatment process can improve the abrasion resistance and hardness of the first semiconductor thin film 120 and the second semiconductor thin film 130, which can maintain the structure and further solve the issues of environmental damage and poor quality generated by other commodities. Heat energy applied to the film surface modification is used when heating the first semiconductor thin film 120 and the second semiconductor thin film 130. This means a thin film surface treatment is used for surface modification of the first semiconductor thin film 120 and the second semiconductor thin film 130. The surface treatment is practiced by the plasma surface modification or laser surface modification. In addition, the substrate 110 of the present invention is selected from the group consisting of Si, SiO₂, metal, GaAs, printed circuit board, sapphire substrate, metal nitride, glass substrate, and ceramic substrate. Different substrates 110 will lead to different coating effects of the first semiconductor thin film 120 and the second semiconductor thin film 130.

### Embodiment 1

In order to increase the hydrophilic properties of the first semiconductor thin film 120 and the second semiconductor thin film 130, different molar ratios of TEOS are added when the heating temperature is 300° C. To carry out analysis of hydrophobic and hydrophilic properties, the first semiconductor thin film 120 and the second semiconductor thin film 130 are irradiated with UV light for 5 minutes. The results are shown in Table I.

TABLE I
Contact angle analysis of the first semiconductor
thin film and the second semiconductor thin film.

| TEOS (mole ratio) | 0.01 | 0.05 | 0.08 | 0.12 |
|---|---|---|---|---|
| The first semiconductor thin film (degree) | 25 | 34 | 55 | 68 |
| The second semiconductor thin film (degree) | 35 | 45 | 61 | 72 |

### Embodiment 2

The difference between this embodiment and the first embodiment is that different molar ratios of TEOS are added when the heating temperature is 400° C. To carry out analysis of hydrophobic and hydrophilic properties, the first semiconductor thin film 120 and the second semiconductor thin film 130 are irradiated with UV light for 5 minutes. The results are shown in Table II.

TABLE II
Contact angle analysis of the first semiconductor
thin film and the second semiconductor thin film.

| TEOS (mole ratio) | 0.01 | 0.05 | 0.08 | 0.12 |
|---|---|---|---|---|
| the first semiconductor thin film (degree) | 29 | 38 | 57 | 69 |
| the second semiconductor thin film (degree) | 38 | 47 | 67 | 75 |

According to the compound semiconductor thin film with an anti-fog function and the manufacturing method thereof of the present invention, the semiconductor thin film combines the dense and porous-needle configuration to decrease the contact angle of water and achieve hydrophilic membrane with long available time.

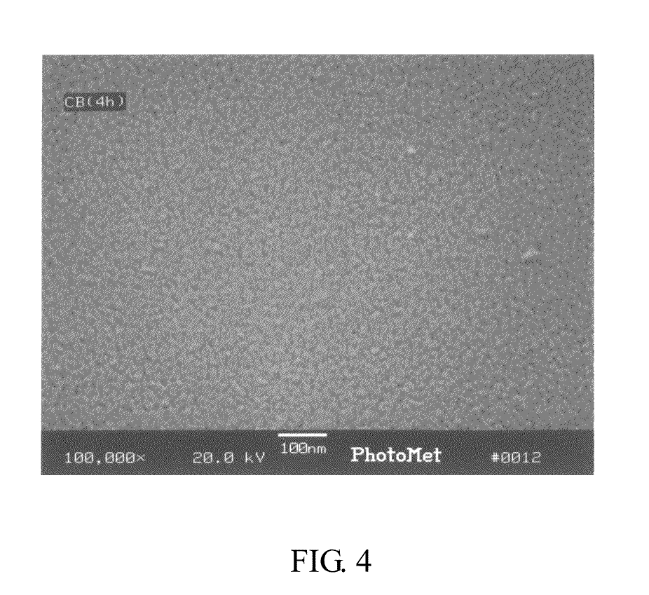

Please refer to FIG. 4, which is a SEM image of the first semiconductor thin film 120 of the present invention. Furthermore, deciding on the changing the contact angle of water and its persistence depends on two factors. One is the flatness and thickness of the dense structure of the first semiconductor thin film 120, which can store energy. The other is the density and thickness (micron degree), of the porous needle-like structure of the second semiconductor thin film 130, which can absorb and release energy. The ideal thicknesses of the first semiconductor thin film 120 and the second semiconductor thin film 130 of the present invention are between 10 nm and 10 microns. It must be noted that the greater thickness of the first semiconductor thin film 120 and the second semiconductor thin film 130 can improve the functionality of decreasing the contact angle of water.

In summary, the functions and advantages of the compound semiconductor thin film with an anti-fog function according to the present invention are:
1. At low temperature condition, combining the dense semiconductor thin film and the porous-needle semiconductor thin film can decrease the contact angle of water.
2. Processing a film surface modification by applying heat energy not only enhances the mechanical strength of thin film, but also forms a hydrophilic anti-fog thin film with a long lifetime.
3. The greater thickness of the dense semiconductor thin film and the porous-needle semiconductor thin film can improve the functionality of decreasing the contact angle of water.

While the present invention has been described by way of example and in terms of the preferred embodiments, it is to be understood that the invention need not be limited to the disclosed embodiments. On the contrary, it is intended to cover various modifications and similar arrangements included within the spirit and scope of the appended claims, the scope of which should be accorded the broadest interpretation so as to encompass all such modifications and similar structures.

What is claimed is:

1. A compound semiconductor thin film with an anti-fog function, comprising:
a first semiconductor thin film, coated on a substrate surface, compounded from a metal organic compound and a hydrocarbon compound, forms a dense structure at a first heating temperature between 300° C. and 1000° C.; and
a second semiconductor thin film, coated on the surface of the first semiconductor thin film, compounded from the metal organic compound, the hydrocarbon compound and an organic additive, forms a porous-needle structure at a second heating temperature between 300° C. and 1000° C.; the pore size of the porous-needle structure is between 1 nm and 25 nm.

2. The compound semiconductor thin film as claimed in claim 1, wherein the first temperature and the second temperature are between 400° C. and 600° C.

3. The compound semiconductor thin film as claimed in claim 1, wherein the metal organic compound is selected from the group consisting of (OR)ₓ M-O-M(OR)ₓ, (R)_{y}(OR)_{x-y} M-O-M(OR)_{x-y}(R)_{y}, M(OR)ₓ, M(OR)_{x-y}(R)_{y}, (OR)ₓ M-O-M(OR)ₓ, where R is selected from the group consisting of alkyl-base, alkenyl-base, aryl-base, haloalkyl-base, and hydrogen; M is selected from the group consisting of Al, Fe, Ti, Zr, Hf, Si, Rh, Cs, Pt, In, Sn, Au, Ge, Cu, and Ta; x is larger than y; x is one of 1, 2, 3, 4, and 5; and y is one of 1, 2, 3, 4, and 5.

4. The compound semiconductor thin film as claimed in claim 1, wherein the hydrocarbon compound is selected from the group consisting of alcohols, ketones, ethers, phenols, aldehydes, esters, and amines.

5. The compound semiconductor thin film as claimed in claim 1, wherein the organic additive is selected from the group consisting of polyols, hydrocarbon compounds, and polymers.

6. The compound semiconductor thin film as claimed in claim 1, wherein the first semiconductor thin film and the second semiconductor thin film participate in a surface modification by a surface treatment.

7. A method of preparing compound semiconductor thin film with anti-fog function, comprising the following steps:
putting a metal organic compound and a hydrocarbon compound into a reaction system to form a first sol, with a temperature of the reaction system between 25° C. and 200° C.;
dipping a substrate in the first sol to form a first semiconductor thin film on the substrate surface;
heating the first semiconductor thin film at a first heating temperature between 300° C. and 1000° C. to form a dense structure;
putting the metal organic compound, the hydrocarbon compound, and an organic additive into the reaction system to form a second sol;
dipping the first semiconductor thin film in the second sol to form a second semiconductor thin film on the surface of the first semiconductor thin film; and
heating the second semiconductor thin film at a second heating temperature between 300° C. and 1000° C. to form a porous-needle structure with pore size between 1 nm and 25 nm.

8. The method as claimed in claim 7, wherein the first temperature and the second temperature are between 400° C. and 600° C.

9. The method as claimed in claim 7, wherein the metal organic compound is selected from the group consisting of (OR)ₓ M-O-M(OR)ₓ, (R)_{y}(OR)_{x-y} M-O-M(OR)_{x-y}(R)_{y}, M(OR)ₓ, M(OR)_{x-y}(R)_{y}, (OR)ₓ M-O-M(OR)ₓ, where R is selected from the group consisting of alkyl-base, alkenyl-base, aryl-base, haloalkyl-base, and hydrogen; M is selected from the group consisting of Al, Fe, Ti, Zr, Hf, Si, Rh, Cs, Pt, In, Sn, Au, Ge, Cu, and Ta; x is larger than y; x is one of 1, 2, 3, 4, and 5; and y is one of 1, 2, 3, 4, and 5.

10. The method as claimed in claim 7, wherein the step of heating the first semiconductor thin film and the second semiconductor thin film at the temperature between 300° C. and 1000° C. further comprises a surface treatment for surface modification.
